(19) United States
(12) Patent Application Publication
(10) Pub. No.: US 2026/0094792 A1
(43) Pub. Date: Apr. 2, 2026

(54) CONTAMINATION DETECTION SYSTEM AND METHOD

(71) Applicant: Applied Materials, Inc., Santa Clara, CA (US)

(72) Inventor: Wolfgang Aderhold, Santa Clara, CA (US)

(21) Appl. No.: 18/901,727

(22) Filed: Sep. 30, 2024

(51) Int. Cl. H01J 37/32

(52) U.S. Cl. CPC H01J 37/32862; H01J 2237/2445; H01J 2237/24585; H01J 2237/24592

(57) ABSTRACT

Described herein is a method for detecting contaminations in a process chamber is provided. The method includes flowing a gas into a process chamber, and igniting a flame in the process chamber at a contact region between the gas a surface in the process chamber. The method may also include measuring one or more properties of the flame using an optical sensor, and identifying a contamination on the surface based on the one or more properties of the flame.

### TECHNICAL FIELD

Embodiments of the present disclosure relate, in general, to a method for detecting contamination in a process chamber. In one embodiment, the method includes measuring a property of a flame to detect a contamination of the surface in the process chamber.

### BACKGROUND

Various manufacturing processes expose semiconductor process chamber components to high temperatures, high energy plasma, a mixture of corrosive gases, high stress, and combinations thereof. These extreme conditions may erode and/or corrode the chamber components, by forming contaminants on the surface of the chamber components. These contaminants may increase the chamber components' susceptibility to defects, and may affect the efficiency of the process chamber. It may be advantageous to be able to detect contaminants as they form in the process chamber.

Current processes to detect contaminants in a process chamber may include processing a wafer in the process chamber, removing the wafer from the process chamber, and then analyzing the wafer and its properties to determine if there are any contaminants. However, this involves post cycle processes that are performed on a wafer after it has been processed by the processing chamber, making it inefficient.

### SUMMARY

In some embodiments of the present disclosure, methods of detecting contamination in a process chamber are provided. In one embodiment, the method may include flowing a gas into a process chamber. The method may further include igniting a flame in the process chamber at a contact region between the gas and a surface in the process chamber; and measuring one or more properties of the flame using an optical sensor. The method may further includes identifying a contamination on the surface based on the one or more properties of the flame.

In another embodiment of the present disclosure, a system is provided for detecting contaminants in a process chamber. The system may include a process chamber and a window attached to the process chamber. The system may further include a gas nozzle configured to distributed at least one gas into the process chamber. The system may further include an optical sensor on the outside of the process chamber, wherein the optical sensor may be configured to measure one or more properties of a flame at a contact between the at last one gas and a surface within the process chamber through the window. The system may further include a computing device to identify a contamination of the surface based on the one or more properties of the flame.

In yet another embodiment of the present disclosure, a non-transitory computer readable medium having instructions thereon, which when executed by a processing device, cause the processing device to receive one or more properties of a flame from an optical sensor from a process chamber.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of one embodiment of a processing chamber.

FIG. 2 is a flow chart representing a method for detecting contaminants on a surface in the process chamber.

FIG. 3 is a block diagram illustrating a computer system, according to certain embodiments.

FIG. 4 is an example of the spectra of Na according to an embodiment.

FIG. 5 is an example of the spectra of Fe according to an embodiment.

FIG. 6 is an example of the spectra of Cr according to an embodiment.

FIG. 7 is an example of the spectra of Ni according to an embodiment.

### DETAILED DESCRIPTION

Chamber components are used in a variety of ways during the manufacturing process of devices such as semiconductor devices. During a manufacturing process, numerous contaminants may form within a process chamber. These contaminants may include, but are not limited to, a metal fluoride, iron, copper, sodium, or a combination thereof. Over time these contaminants may accumulate, such that the performance of the process chamber is impacted. This may prompt maintenance of the process chamber, such as replacement of one or more chamber components of the process chamber, cleaning of the process chamber, and so on. The present disclosure includes methods to perform in-situ detection of contaminants in a process chamber. Embodiments of the present disclosure lead to expanded lifespan of one or more chamber components of process chambers.

Preventative maintenance and/or other maintenance may be performed on a process chamber periodically. Such maintenance may include exposing an interior of the process chamber to outside contaminants, which may include organic contaminants, metal contaminants, and so on. After maintenance is performed on a process chamber, the process chamber is typically seasoned by performing one or more seasoning processes (e.g., which may include performing one or more wafer runs using the process chamber). After seasoning of the process chamber is complete, metal contamination analysis is traditionally performed using one or more monitor wafers. The monitor wafers are processed in the process chamber, are removed from the process chamber, and are then analyzed to identify any metal contamination thereon.

In embodiments, rather than removing monitor wafers from a process chamber to analyze the monitor wafers after processing, optical measurements may be performed of the process chamber during processing. The optical measurements may be continually or periodically gathered during processing to repeatedly determine whether contamination is detected in the process chamber. If the optical measurements are performed during seasoning, this technique can be used to determine the exact end point of seasoning. Additionally, the optical measurements may be performed during other processing (e.g., during processing between processing of product substrates) to detect the occurrence of contamination. If contamination is detected, then a cleaning procedure can be automatically scheduled.

Embodiments disclosed herein describe a method for detecting a contaminant in a process chamber in-situ (e.g., during processing). In an embodiment, the method may include flowing a gas into a process chamber. The method may also include igniting a flame in the process chamber at a contact region between the gas and a surface in the process chamber (e.g., a surface of a substrate such as a monitor wafer). The method may include measuring one or more properties of the flame using an optical sensor. The method may further include identifying a contamination on the surface based on the one or more properties of the flame.

When using an optical sensor, the sensor is able to detect any contaminants that form while a process is running. That is, the sensor can detect contaminants in the high temperature environments of the process chamber. It has been found that metal from chamber walls can get into the atmosphere of the process chamber, which affects the conditions of the process chamber. These metals may include copper, iron and/or sodium and can be detected in embodiments to prevent any contaminants from affecting the chamber components in the process chamber and/or processed substrates. The present disclosure has found that by including the optical sensor in a current process chamber, the process chamber can be efficiently monitored to detect any contaminants (e.g. metal contaminants), in an environment of the process chamber (e.g., metal that is airborne) by analyzing induced flames in the process chamber, as will be described herein.

In some embodiments, the optical sensor may include a spectrometer as understood by one of skill in the art. In some embodiments, the optical sensor may include a filter. The filter may filter out wavelengths of light that may be outside of a target wavelength associated with a specific type of contamination (or outside multiple wavelengths, each associated with a different type of metal contamination). A computing device may be used to store data relating to the target wavelengths and specific type of contaminations, which can then analyze the data from the optical sensor. The optical sensor may also measure an intensity of the flame based on filtered light that has been filtered by the filter to determine a concentration of a metal contaminant.

In some embodiments, the target wavelength(s) may be selected from a range from about 200 to about 1000 nm. In other embodiments, the target wavelength(s) may be in a range from about 200 nm to about 1000 nm, about 250 nm to about 950 nm, about 300 nm to about 900 nm, about 350 nm to about 850 nm, about 400 nm to about 800 nm, about 450 nm to about 750 nm, or about 500 nm to about 700 nm, or any sub-range herein.

In some embodiments, the target wavelength(s) may correspond to a wavelength that is produced by iron contamination, copper contamination, and/or sodium contamination. In an embodiment, the target wavelength(s) corresponds to a wavelength that is produced by iron contamination.

In some embodiments, the method may further include determining that the flame outputs light having a wavelength from about 200 nm to about 1000 nm, and identifying the contamination based on the wavelength.

In some embodiments, the method may further include initiating a cleaning process for the process chamber responsive to identifying the contamination. In some embodiments, the cleaning process may include applying a purge gas to the process chamber. The purge gas may include an inert carrier gas (such as nitrogen or air).

In some embodiments, the method may further include performing a seasoning process for the process chamber responsive to identifying the contamination. In some embodiments, the method includes detecting a metal contamination during the seasoning process. The detected metal contamination may be used to determine when the seasoning process is complete in some embodiments.

In one embodiment, a system for detecting contaminants in a process chamber is provided. The system may include a process chamber, and a window attached to the process chamber. The system may also include a gas nozzle configured to distribute at least one gas into the process chamber. The system may also include an optical sensor on the outside of the process chamber. The optical sensor may be configured to measure one or more properties of a flame at a contact between the at least one gas and a surface within the process chamber through the window. The system may also include a computing device to identify a contamination of the surface based on the one or more properties of the flame.

In some embodiments, the window may be a quartz window. In some embodiments, the surface may include at least one of a surface of a wafer, a surface of a substrate support, or a surface of a process ring kit. In some embodiments, the at least one gas from the gas nozzle may be hydrogen, oxygen, or a combination thereof.

As used herein, the term “contamination” and “contaminant” may be used interchangeably, but is to be understood as unwanted metals, compounds or elements in the process chamber.

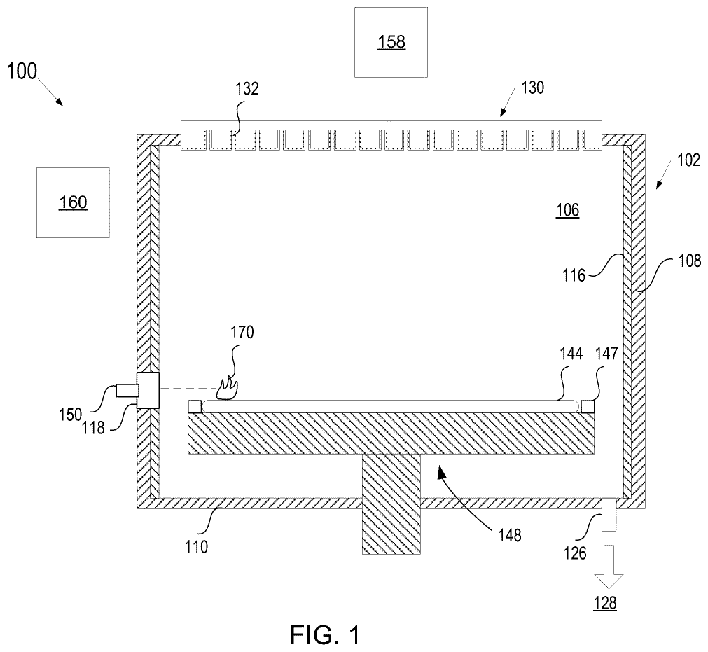

Referring now to the figures, FIG. 1 is a sectional view of a processing chamber 100 (e.g., a semiconductor processing chamber) having one or more chamber components in accordance with embodiments of the present disclosure. In some embodiments, the processing chamber 100 may be used for processes in which a corrosive plasma environment and/or corrosive chemistry is provided. For example, the processing chamber 100 may be a chamber for a plasma etch reactor (also known as a plasma etcher). In some embodiments, the processing chamber 100 is chamber configured to perform rapid thermal processor (RTP). Examples of chamber components of the processing chamber 100 are a substrate support assembly 148, an electrostatic chuck (ESC), a ring (e.g., a process kit ring or single ring), a chamber wall, a base, a showerhead 130, a gas distribution plate, a liner, a liner kit, a shield, a plasma screen, a flow equalizer, a cooling base, a chamber viewport, a chamber lid, a nozzle, process kit rings, and so on.

In one embodiment, the processing chamber 100 includes a chamber body 102 and a showerhead 130 that enclose an interior volume 106. The showerhead 130 may or may not include a gas distribution plate. For example, the showerhead may be a multi-piece showerhead that includes a showerhead base and a showerhead gas distribution plate bonded to the showerhead base. Alternatively, the showerhead 130 may be replaced by a lid and a nozzle in some embodiments, or by multiple pie shaped showerhead compartments and plasma generation units in other embodiments. The chamber body 102 may be fabricated from aluminum, stainless steel or other suitable material. The chamber body 102 generally includes sidewalls 108 and a bottom 110. In embodiments, the sidewalls 108 may include a window 118. In some embodiments, the window 118 may be a transparent crystal, such as a transparent ceramic material, sapphire, diamond, quartz, silicon carbide, or a combination thereof.

An optical sensor 150 may be disposed outside of the process chamber 100, and may receive optical data from inside the interior volume 106 through the window 118. The optical sensor 150 may be configured for measuring one or more properties of a flame 170 ignited in the interior volume 106 at a contact of a gas and a surface of substrate 144 and/or another surface (e.g., of a process kit ring, substrate support, etc. within the process chamber 100.

In various embodiments, processing chamber 100 may include a window 118, which may be, for example, a transparent crystal, at least a part of which is embedded in a wall and/or liner of the processing chamber 100. In some embodiments, a flame may be ignited within the process chamber 100, and light from the flame may be captured and analyzed by optical sensor 150. In some embodiments, the optical sensor 150 comprises a spectrometer, which may perform optical emission spectrometry (OES) on the captured light. The spectrometer may, for example, perform a spectrographic analysis of the light to determine one or more spectrum of the light that may be used to determine a concentration of one or more metal contaminants within the interior volume 106 of the processing chamber 100.

In some embodiments, the optical sensor 150 is a camera with one or more filters disposed in front of a lens of the camera. The filters may pass wavelengths of one or more wavelengths or wavelength ranges of interest, and may block other wavelengths. The optical sensor 150 may determine the intensities of one or more wavelengths, and based on the determined intensities may determine a concentration of one or more contaminants within the interior volume 106 of the processing chamber 100.

A controller 160 (e.g., a tool and equipment controller) may control various aspects of the processing chamber 100, optical sensor 150, and/or other systems, such as gas pressure in the processing chamber 100, individual gas flows, spatial flow ratios, temperature of various chamber components, radio frequency (RF) or electrical state of the processing chamber 100, and so on. The controller 160 may receive signals from and send commands to one or more components of the processing chamber 100. The controller 109 may thus control the initiation and cessation of processing, may adjust a deposition rate, type or mix of deposition composition, and the like. The controller 160 may further receive and process sensing data from various sensors, such as optical sensor 150.

In various embodiments, the controller 160 includes (or is coupled to) a processing device and is coupled to the optical sensor 150. The processing device may be configured to receive and process sensing data, including the results of OES and/or intensities of wavelengths of light determined by optical sensor 150. Depending on results of analyzing the received spectral data and/or intensity data, the controller 160 may perform one or more actions, such as schedule cleaning of the process chamber, end seasoning of the process chamber 100, schedule maintenance of the process chamber 100, and so on.

The controller 160 may be and/or include a computing device such as a personal computer, a server computer, a programmable logic controller (PLC), a microcontroller, and so on. The controller 160 may include (or be) one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. The controller 150 may include a data storage device (e.g., one or more disk drives and/or solid state drives), a main memory, a static memory, a network interface, and/or other components. The controller 150 may execute instructions to perform any one or more of the methodologies and/or embodiments described herein. The instructions may be stored on a computer readable storage medium, which may include the main memory, static memory, secondary storage and/or processing device (during execution of the instructions). An outer liner 116 may be disposed adjacent the sidewalls 108 to protect the chamber body 102. The outer liner 116 may be a halogen-containing gas resist material such as Al₂O₃ or Y₂O₃.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewalls 108 of the chamber body 102 and/or on a top portion of the chamber body. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or carrier gases to the interior volume 106 through the showerhead 130 or lid and nozzle. Examples of process gas that may be delivered by the gas panel 158 and used to process substrates/samples in the processing chamber 100 include a silicon containing gas, halogen-containing gases, such as C₂F₆, SF₆, HBr, NF₃, CF₄, CHF₃, CH2F3, F, NF₃, Cl₂, CCl₄, BCl₃ and SiF₄, among others, and/or other gases such as O₂ or N₂O. Examples of carrier gases (also referred to herein as a diluent) include N₂, He, Ar, and other gases inert to process gases (e.g., non-reactive gases). The gas panel 158 may also include a gas nozzle to deliver at least one of hydrogen gas, oxygen gas, or a combination thereof. The showerhead 130 includes multiple gas delivery holes 132 throughout the showerhead 130. The showerhead 130 may be or may include aluminum, anodized aluminum, an aluminum alloy (e.g., Al 6061), or an anodized aluminum alloy. In some embodiments, the showerhead includes a gas distribution plate (GDP) bonded to the showerhead. The GDP may be, for example, Si or SiC. The GDP may additionally include multiple holes that line up with the holes in the showerhead.

In some embodiments, the process chamber 100 further includes an ignitor (not pictured) to ignite a flame in the interior volume 106 of the process chamber. In particular, the flame may ignite at a contact region between the gas and a surface in the process chamber, such as a surface of the substrate 144. The flame may be ignited by heating the process chamber to a temperature of about 500° C. to about 1000° C. such that the gas that is flowed through combusts. In some embodiments, the igniter comprises one or more heating element or heater. The heating element or heater may include, for example, a resistive heating element, an optical heating element (e.g., a heat lamp), or the like.

A substrate support assembly 148 is disposed in the interior volume 106 of the processing chamber 100 below the showerhead 130. The substrate support assembly 148 holds a substrate 144 (e.g., a wafer) during processing. The substrate support assembly 148 may include a chuck (e.g., an electrostatic chuck) that secures the substrate 144 during processing. The substrate support assembly 148 may include a metal cooling plate bonded to the chuck, and/or one or more additional components. An inner liner may cover a periphery of the substrate support assembly 148. The inner liner may be a halogen-containing gas resist material such as Al₂O₃ or Y₂O₃. In some embodiments, a process kit ring 147 is disposed around the substrate 144. The process kit ring 147 may be positioned such that a top of the process kit ring 147 is about coplanar with a top of the substrate 144 in some embodiments.

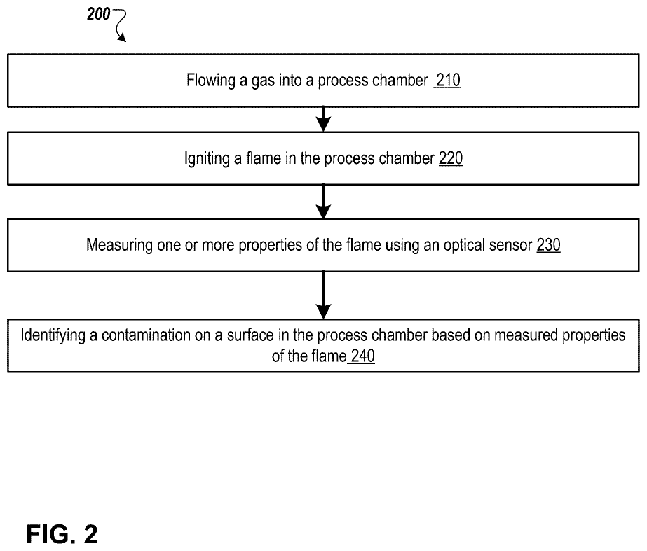

Referring to FIG. 2, a flow chart is provided showing a method 200 for detecting contaminants in a process chamber. In block 210, a gas may be flowed into a process chamber. The gas may include hydrogen, oxygen or a combination. After flowing the gas into a process chamber, a flame may be ignited in the process chamber in block 220. The flame may be ignited at a contact region between the gas and a surface in the process chamber. The surface may include at least one of a surface of a wafer, a surface of a substrate support, or a surface of a process kit ring that may surround the substrate support. The flame may be ignited by heating the process chamber to a target temperature. The target temperature may be in a range of about 500° C. to about 1000° C. in some embodiments.

The method 200 further includes measuring one or more properties of the flame using an optical sensor in block 230. The optical sensor may be placed on or at a window that is on one side of the process chamber. The optical sensor may be perpendicular to the flame in the process chamber in some embodiments. In some embodiments, the process kit ring is approximately horizontal. In some embodiments, the optical sensor may be placed anywhere along the center of the process chamber such that it is in between the gas distribution plate and substrate of the process chamber described in FIG. 1. In some embodiments, the optical sensor may be a spectrometer. In other embodiments, the optical sensor may be a camera with one or more filter, wherein the filter filters out wavelengths of light that are outside of a target wavelength (or multiple target wavelengths) associated with one or more specific types of contamination. In an embodiment, the optical sensor may include a plurality of filters, wherein each filter is configured to filter out different wavelengths.

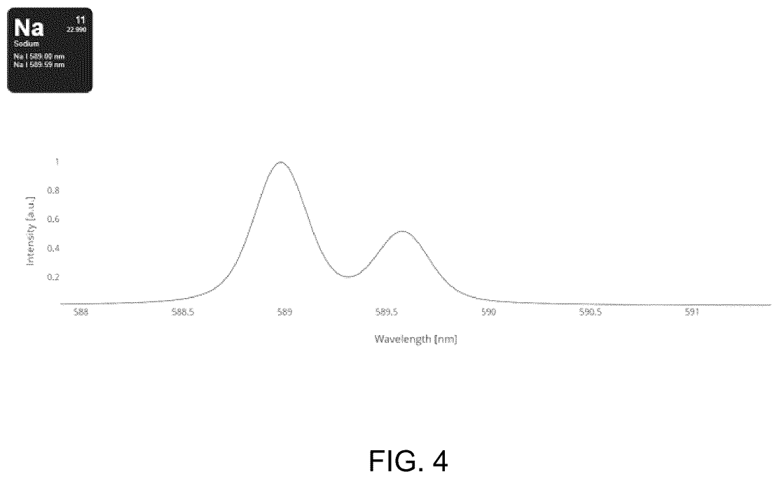

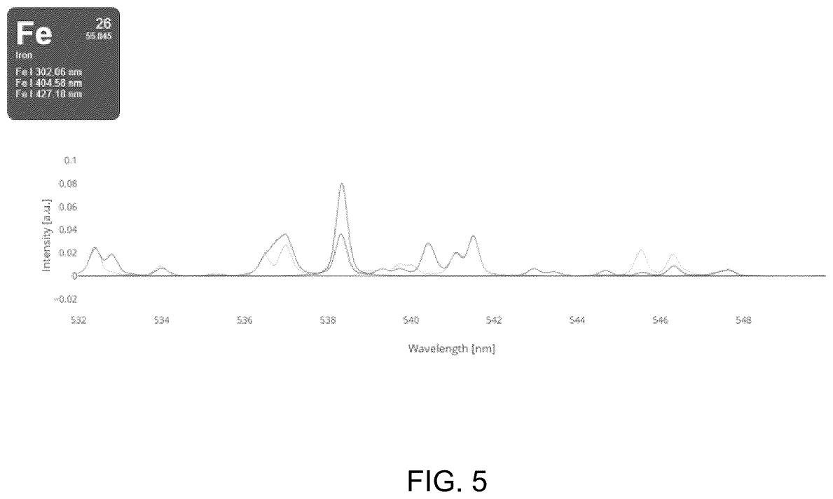

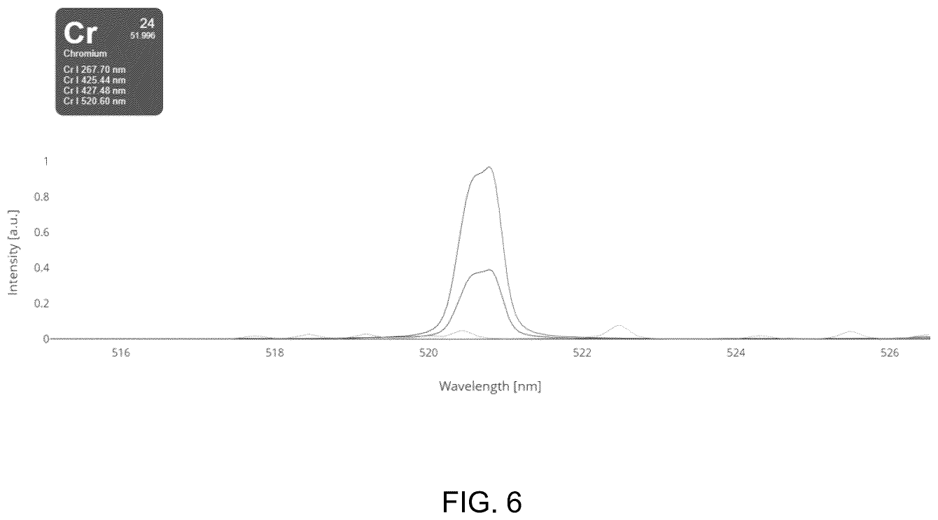

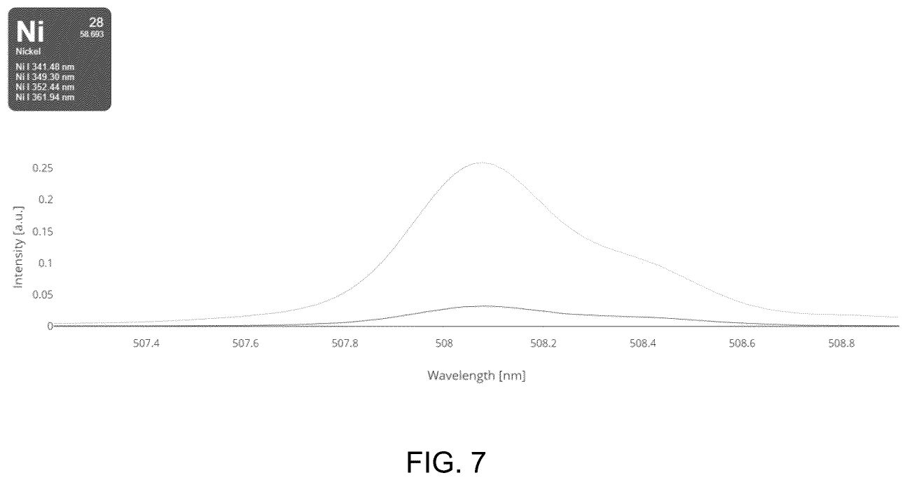

In an example, each type of metal contaminant may have an associated wavelength that is emitted when a flame is burned in the presence of the metal contaminant. The greater the concentration of the metal contaminant, the higher the intensity of light that is output at the wavelength associated with the metal contaminant in question. For example, sodium may cause a flame to output light having a wavelength of about 585 nm to about 590 nm, and iron may cause a flame to output light having a wavelength range of about 200 nm to 1000 nm (e.g., a line at about 200 nm and a line at about 1000 nm). In some embodiments, the wavelength of iron (Fe) may be about 535 nm to about 540 nm, nickel (Ni) may be about 505 nm to about 510 nm, sodium (Na) may be about 588 nm to about 592 nm, and chromium (Cr) may be about 520 nm to about 525 nm. FIGS. 4-7 show the spectra that could be generated when measured by the optical sensor of Na, Fe, Cr, and Ni, respectively. The intensity of light at one or more wavelengths may be determined by the optical sensor (e.g., by a spectrometer or camera with filter(s)).

The optical sensor provides the emission spectra (e.g., intensities of light at one or more wavelengths) to a computer system. The computer system may then present and/or analyze the received spectra/wavelength intensity data. The emission spectra may illustrate the properties of the flame through peaks of one or more wavelengths of light, where each peak may correspond to a particular type of metal contaminant.

In some embodiments, the optical sensor may be calibrated to a target wavelength. The calibration includes gathering information about the background conditions in the process chamber such that when a contaminant is present, it can be easily distinguished from background conditions. Calibration may be performed, for example, by using a particular metal contaminant as a tracer that is introduced into a gas that is fed to the interior of the process chamber to generate a flame. For example, the metal contaminant may be added to a hydrogen gas that is flowed into the process chamber. A known amount of the metal contaminant may be input into the gas, and a peak height of a particular wavelength of light may be determined that corresponds to the known amount of the metal contaminant. The peak height may then be recorded for that amount of trace metal contaminant. This may be performed for one or more concentration levels of the contaminant to calibrate the system. In some embodiments, an emission spectra output by a flame that is generated in a clean environment (e.g., with no metal contaminants) may be measured, and may be subtracted from an emission spectra measured from a test environment to determine an amount of one or more metal contaminants.

In block 240, a contaminant on the surface is identified based on the one or more properties of the flame. After measuring, the measured properties of the flame by the optical sensor may be delivered to a software to analyze.

In some embodiments, method 200 is performed during a process (e.g., a pyrometry process) performed on a product substrate. In some embodiments, method 200 is performed periodically between processing of product substrates. In such an embodiment, method 200 may be performed using a test substrate.

In some embodiments, method 200 may be performed during an oxidation process that involves igniting a flame on a surface of a substrate. The oxidation process may form an oxide coating on the surface of the substrate. The optical sensor may be able to detect any contaminants that form during this process, while the coating process is performed. If metal contamination is detected during this process that is above a threshold amount for one or more types of metal contaminants, one or more corrective actions may be taken to address the identified metal contamination. For example, processing logic may schedule a cleaning of the processing chamber, a maintenance of the processing chamber, and so on.

In some embodiments, method 200 may be performed during a seasoning process of the processing chamber. The seasoning process may be performed after the processing chamber has been cleaned or after maintenance has been performed on the processing chamber. In some embodiments, processing logic continuously or periodically detects an emission spectra of a flame ignited in the processing chamber during the seasoning process. Once the amount of detected metal contaminants reaches a target level (e.g., zero), then the seasoning process may end and the processing chamber may be ready to process product substrates.

In some embodiments, after identifying a contaminant is present in the process chamber, a cleaning process may be initiated. In some embodiments, method 200 is performed during a cleaning process, and/or between iterations of a cleaning process. The cleaning process may be performed or repeated until the light intensity of one or more target wavelengths falls below a threshold level indicating that metal contamination is no longer present. Once metal contamination is removed, the processing chamber may then be used to process additional product substrates.

In some embodiments, the measured one or more properties (e.g., intensities of one or more wavelengths) of the flame determined in block 230 may be inputted into a trained machine learning model that has been trained to estimate an amount of one or more types of metal contaminants. The trained machine learning model may then output an estimated wavelength or wavelengths and/or indicate concentrations of one or more contaminant.

In embodiments, trained machine learning models are edge-based models that execute on the processing chamber themselves rather than on remote computing devices. Training of the machine learning models may be performed remotely, after which trained machine learning models may be transferred to the processing chamber, or may be performed on the processing chamber. Retraining or updating of training of the machine learning models may be performed periodically or continuously on the processing chamber. By having execution and/or training (including retraining) of the machine learning models to the processing chamber, latency between generation of sensor measurements and making decisions based on such sensor measurements can be significantly reduced. This improves an ability to make real-time decisions for process chambers. Additionally, moving the decision making to the processing chamber reduces an amount of data that is transmitted over a network, increases efficiency, and increases a speed with which decisions can be made. For example, a decision of when to stop an etch process can be made within seconds or fractions of a second from when sensor data that triggers such a decision is received in embodiments that include a machine learning model trained to detect an etch endpoint.

In some embodiments, the optical sensor may be connected to a computing device executing one or more trained machine learning model. The trained machine model(s) may be trained to estimate wavelength(s) representative of contaminants in a flame and/or to estimate contaminants based on the optical sensor measurements at one or more locations.

In one embodiment, one or more of the trained machine learning models is a regression model trained using regression. Examples of regression models are regression models trained using linear regression or Gaussian regression. A regression model predicts a value of Y given known values of X variables. The regression model may be trained using regression analysis, which may include interpolation and/or extrapolation. In one embodiment, parameters of the regression model are estimated using least squares. Alternatively, Bayesian linear regression, percentage regression, leas absolute deviations, nonparametric regression, scenario optimization and/or distance metric learning may be performed to train the regression model.

In one embodiment, one or more of the trained machine learning models are decision trees, random forests, support vector machines, or other types of machine learning models.

In one embodiment, one or more of the trained machine learning models is an artificial neural network (also referred to simply as a neural network). The artificial neural network may be, for example, a convolutional neural network (CNN) or a deep neural network. In one embodiment, processing logic performs supervised machine learning to train the neural network.

Artificial neural networks generally include a feature representation component with a classifier or regression layers that map features to a target output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs). The neural network may be a deep network with multiple hidden layers or a shallow network with zero or a few (e.g., 1-2) hidden layers. Deep learning is a class of machine learning algorithms that use a cascade of multiple layers of nonlinear processing units for feature extraction and transformation. Each successive layer uses the output from the previous layer as input. Neural networks may learn in a supervised (e.g., classification) and/or unsupervised (e.g., pattern analysis) manner. Some neural networks (e.g., such as deep neural networks) include a hierarchy of layers, where the different layers learn different levels of representations that correspond to different levels of abstraction. In deep learning, each level learns to transform its input data into a slightly more abstract and composite representation.

Some trained machine learning models of the processing tool may be used for multiple different process chambers that have a common process chamber type with sensors (e.g., temperature sensors) at same locations and that are used to perform the same or similar processes. For example, a first process chamber and a second process chamber may both be etch chambers that perform a same etch process. A trained machine learning model may be used to determine when to schedule each of first process chamber and second process chamber for maintenance, when to cease a seasoning process after maintenance, and so on.

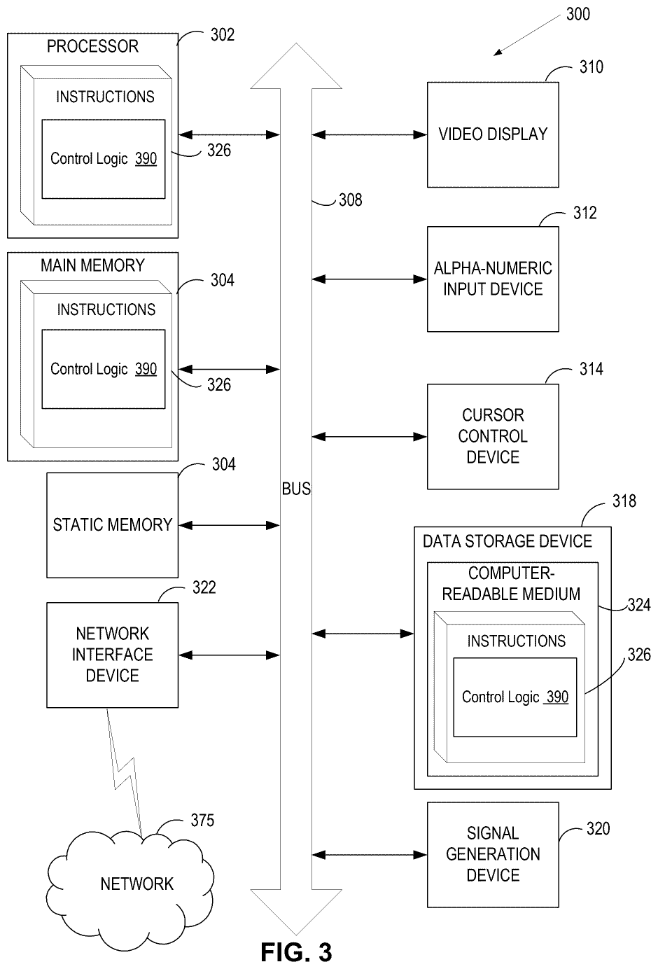

FIG. 3 is a block diagram illustrating a computer system 300, according to some embodiments. In some embodiments, computer system 300 corresponds to controller that may be included in the process chamber. In some embodiments, computer system 300 may be connected (e.g., via a network, such as a Local Area Network (LAN), an intranet, an extranet, or the Internet) to other computer systems. The term “computer” shall include any collection of computers that individually or jointly execute a set (or multiple sets) of instructions to perform any one or more of the methods described herein.

In a further aspect, the computer system 300 may include a processing device 302, a volatile memory 304 (e.g., Random Access Memory (RAM)), a non-volatile memory 306 (e.g., Read-Only Memory (ROM) or Electrically-Erasable Programmable ROM (EEPROM)), and a data storage device 318, which may communicate with each other via a bus 308.

Processing device 302 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 300 may further include a network interface device 322 (e.g., coupled to network 374). Computer system 300 also may include a video display unit 310 (e.g., an LCD), an alphanumeric input device 312 (e.g., a keyboard), a cursor control device 314 (e.g., a mouse), and a signal generation device 320.

In some embodiments, data storage device 318 may include a non-transitory computer-readable storage medium 324 (e.g., non-transitory machine-readable medium) on which may store instructions 326 encoding any one or more of the methods or functions described herein, including instructions for control logic 390 that may monitor concentrations of gases, radicals, etc., and determine changes to process chambers and/or remote plasma sources based on detected concentrations.

Instructions 326 may also reside, completely or partially, within volatile memory 304 and/or within processing device 302 during execution thereof by computer system 300, hence, volatile memory 304 and processing device 302 may also constitute machine-readable storage media.

While computer-readable storage medium 324 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A method comprising:
flowing a gas into a process chamber;
igniting a flame in the process chamber at a contact region between the gas and a surface in the process chamber;
measuring one or more properties of the flame using an optical sensor; and
identifying a contamination on the surface based on the one or more properties of the flame.

2. The method of claim 1, wherein the optical sensor comprises a spectrometer.

3. The method of claim 2, wherein the optical sensor comprises a filter, wherein the filter filters out wavelengths of light that are outside of a target wavelength associated with a specific type of contamination, and wherein the optical sensor measures an intensity of the flame based on filtered light that has been filtered by the filter.

4. The method of claim 3, wherein the target wavelength is selected from a range from 200 to 1000 nm.

5. The method of claim 3, wherein the target wavelength corresponds to a wavelength that is produced by iron contamination.

6. The method of claim 1, further comprising:
determining that the flame outputs light having a wavelength of from 200 to 1000 nm; and
identifying the contamination based on the wavelength.

7. The method of claim 1, further comprising:
initiating a cleaning process for the process chamber responsive to identifying the contamination.

8. The method of claim 7, further comprising performing a seasoning process for the process chamber responsive to identifying the contamination.

9. A system comprising:
a process chamber;
a window attached to the process chamber;
a gas nozzle configured to distributed at least one gas into the process chamber;
an optical sensor on the outside of the process chamber, wherein the optical sensor is configured to measure one or more properties of a flame at a contact between the at least one gas and a surface within the process chamber through the window; and
a computing device to identify a contamination of the surface based on the one or more properties of the flame.

10. The system according to claim 9, wherein the surface comprises at least one of a surface of a wafer, a surface of a substrate support, or a surface of a process ring kit.

11. The system of claim 9, wherein the at least one gas comprises hydrogen, oxygen, or a combination thereof.

12. The system of claim 9, wherein the optical sensor comprises a spectrometer.

13. The system of claim 9, wherein the optical sensor comprises a filter, wherein the filter is configured to filter out wavelengths of light that are outside of a target wavelength associated with a specific type of contamination, and where the optical sensor is configured to measure an intensity of the flame based on filtered light that has been filtered by the filter.

14. The system of claim 13, wherein the target wavelength is selected from a range from 200 to 1000 nm.

15. The system of claim 13, wherein the target wavelength corresponds to a wavelength that is produced by iron contamination.

16. A non-transistory computer readable medium having instructions thereon, which, when executed by a processing device, causes the processing device to receive one or more properties of a flame from an optical sensor from a processing chamber.

17. The non-transistory computer readable medium of claim 16, wherein the flame is at a contact region between a gas and a surface of the process chamber.

18. The non-transistory computer readable medium of claim 17, identifying a contamination of the surface based on the one or more properties of the flame.

19. The non-transistory computer readable medium of claim 18, wherein the identifying the contamination is based on wavelength of light of the flame as determined by the optical sensor.

20. The non-transistory computer readable medium of claim 19, further comprising alerting a user to the wavelength corresponding to the contamination.
